(19) United States
(12) Patent Application Publication
(10) Pub. No.: US 2009/0114267 A1
(43) Pub. Date: May 7, 2009

(54) Clock operated step function solar tracker

(76) Inventor: Bruce A. Thompson, Granite Bay, CA (US)

Correspondence Address: Dr. Bruce A. Thompson, 6700 Auburn Folsom Road, Granite Bay, CA, 95746, US

(21) Appl. No.: 12/290,511

(22) Filed: Nov. 1, 2008

Related U.S. Application Data
(60) Provisional application No. 61/002,045, filed on Nov. 6, 2007.

(51) Int. Cl. H01L 31/042

(52) U.S. Cl. 136/246

(57) ABSTRACT

The present invention describes a solar panel system tracker that closely approximates the output levels of an actively tracked system but at significantly reduced levels of complexity and cost. The present invention is comprised of a clock that generates a five degree step function which moves the solar panel system in five degree increments over the period of the solar day. This provides approximately thirty-five separate adjustments throughout the day, yielding an aggregate output performance of approximately 90 percent compared to a fully tracked system.

This non-provisional utility patent application claims the benefit of priority for U.S. Provisional patent application No. 61/002,045 filed Nov. 06, 2007.

### BRIEF DESCRIPTION

The subject of this invention relates to the alternative energy arts. Specifically, the present invention discloses a solar tracker that operates on the principle of a clock operated step function which provides energy capture performance of near real time tracking systems but at a very economical cost.

### BACKGROUND OF THE INVENTION

Power generation by means of photovoltaic cells (PV) is not new. Individual cells are normally configured in an array of multiple cells to create a specific desired output power. For example, a series/parallel array to provide and output rating of 12 volts at 1.5 amps. This series/parallel arrangement is referred to as a “solar panel,” and power output from the panel is customarily expressed in watts, thus in the preceding example the panel formed by the array would have a nominal rating of 18 watts. Common system design practice is to combine a number of panels to construct larger arrays to create a power source capable of delivering high levels of useful power. This is done by mounting a plurality of solar panels to a common frame. Typical contemporary systems range from two to five kilowatts, but as will be recognized, virtually any output power level can be obtained by increasing the number of panels that are interconnected.

As mentioned panel systems vary enormously in their output capability, however, one common factor is the efficiency of the PV system. It is well understood in the art that a PV cell will produce peak output power output only when the sun's rays are impinging directly on the cell. Any off angle, whether longitudinal or lateral, will result in a rapid decline of the output power. It follows then that the power output of a panel system will suffer in the same way and to the same degree as the individual cells that comprise the system. Of course there are other factors that impact cell output including junction temperature, basic cell transfer efficiency and so forth, but for purposes of the disclosed invention, the discussion is limited to impinging angle issues.

Since the power decrease phenomenon is so well understood, a number of methods have been used to compensate for the time variation of the impinging angle due to the sun's path over time. These methods include simply over-sizing a fixed panel system to account for power loss due to impinging solar angle variation, using focusing means to concentrate the impinging solar light to compensate for solar angle variation, and trackers that move the panel system to constantly face the sun in order to maximize the time the array is subjected to direct impinging light. Each of these, while functional, has one or more serious drawbacks.

The over-sizing of a fixed panel system is highly inefficient and very costly. The theory of this method is to generate enough power during the relatively short period of time when the system is at or near its peak output to compensate for less than maximum output at all other times. As will be discussed in detail below, a 3.6 kilowatt panel system will deliver on average only 65 percent, or 23.4 kilowatts of power on a given day and under similar conditions when compared to a fully tracked panel system.

Focusing methods exist in several different variants; for example, parabolic reflectors or mirror array reflectors. The fundamental way that these systems work is to concentrate the impinging solar light on a target, either a PV array or, more commonly, a boiler. Regardless of the target, the theory is to extract a greater amount of energy in a short period of time by amplifying the incoming solar light. Some of these focusing methods are used in tandem with tracking schemes, described just below.

The focusing method suffers from two serious problems. First, focusing methods cause a buildup of heat on the surface of the panel or target, thus raising the junction temperature of the individual cells. This causes a decrease in output simply due to semiconductor physics. To compensate, cooling methods must be added to maintain a stable junction temperature. This is expensive and complex. Second, while the focusing method increases the output with respect to a fixed panel system, unless it is tracked it, too, has inefficiencies for the same reasons discussed just above.

As is the case for focusing methods, tracking mechanisms come in numerous variants. Common to all of them is the ability of the mechanism, or “tracker”, to follow the sun as it transits the daytime sky. This is accomplished by providing a means for detecting where the sun is in the sky, then driving the solar panel array until it is perpendicular to the impinging light. This method is referred to as active tracking. The primary feature of active tracking is that the solar panel array is moved almost continually as the sun transits its daily arc, keeping the impinging light at an almost exact ninety degree angle to the surface of the array.

Tracking methods also suffer from multiple problems. First, they are complex, requiring specialized knowledge to install and maintain. Second, they are very expensive. Third, in general they exhibit a high failure rate when compared with the other methods described. This is due to the complex mechanisms, use of exotic substances and difficulty in maintaining alignment under certain conditions. The vast majority of the current trackers require bright sunlight in order to track correctly. This is because they operate on a temperature differential—that is, the panels move when an element is exposed to direct sunlight. On overcast days trackers of this type become misaligned in short order.

What would be desirable would be a method and apparatus that will approximate the output levels of an actively tracked panel system while not exhibiting the high cost, high maintenance and loss of alignment problems normally associated with these types of trackers. What would be further desirable would be a system that accomplishes the above yet is simple enough for average alternative energy users to install.

### SUMMARY OF THE INVENTION

The present invention describes a solar panel system tracker that closely approximates the output levels of an actively tracked system but at significantly reduced levels of complexity and cost. The present invention utilizes a clock that generates a five degree step function which moves the solar panel system in five degree increments over the period of the solar day. This provides approximately thirty-five separate adjustments throughout the day, yielding an aggregate output performance of approximately 90 percent compared to a fully tracked system.

The present invention is comprised of a clock, a motor, a set of sensors, a battery and a control system. The control system is further comprised of a charge controller, a power controller, a motor controller and related sensor logic. Sensors used by the system include an AM (morning) sensor, a PM (afternoon) sensor, an AM limit switch, and a PM limit switch. Each of these components is mounted on a clutch plate so that the apparatus of the present invention may be quickly installed or removed for maintenance or relocation.

The clutch plate is formed by a pair of disks: a fixed disk and a movable disk that is free to rotate on top of the fixed disk. The fixed disk has stop holes drilled at five degree increments, into which a pin controlled by a solenoid drops once a given step has occurred. This pin-and-hole combination is used to provide the requisite stability under windy conditions.

The clutch plate assembly attaches to a fixed post via the lower fixed disk. The solar panel system, mounted on a frame, attaches to one end of a panel boom. The center of the panel boom attaches to the moveable disk. A counterweight is attached to the end of the panel boom opposite the solar panel system to create a balance point that is centered over the center of the moveable disk, thereby minimizing the load on the motor.

In operation, the combination of the sensors and the control logic first ascertain that the solar panel system is in the morning position. If not, the logic activates the motor and drives the panels until the AM limit switch disengages the motor. Once in the correct position the clock logic begins the step function process. Each time a step is required the stabilizing pin is lifted, the motor is activated and the panels are moved exactly five degrees. The stabilizing pin is dropped into the next succeeding hole and the process waits until the time has been reached for the next step. At sunset the PM sensor instructs the logic to drive the panels to the morning position and the system goes to sleep until again awakened by the AM sensor.

The method and apparatus of the present invention offer several advantages over the prior art. Among these are much lowered cost, good energy capture performance when compared to actively tracked systems and superior performance when compared with fixed systems. As well as these advantages, the present invention has other advantages discussed in detail below in conjunction with the drawings and figures attached.

### BRIEF DESCRIPTION OF THE DRAWINGS

FIG. 1: is a block diagram of the control system of the present invention.

FIG. 2: is a detailed block diagram of the motor controller of the system of the present invention.

FIG. 3: is a high level flow chart of the method of the present invention.

FIG. 4: is a detailed flow chart of the motor step function of the method of the present invention.

FIG. 5: provides details of the clutch mechanism of the apparatus of the present invention.

FIG. 6: shows the apparatus of the present invention in its normal operational mounting.

FIG. 7: is a schematic of a typical solar day.

FIG. 8: is a graphical representation of the performance of the present invention as compared to other contemporary solutions.

FIG. 8: is a typical output table comparing the performance of the present invention to other contemporary solutions.

### DETAILED DESCRIPTION OF PREFERRED EMBODIMENTS

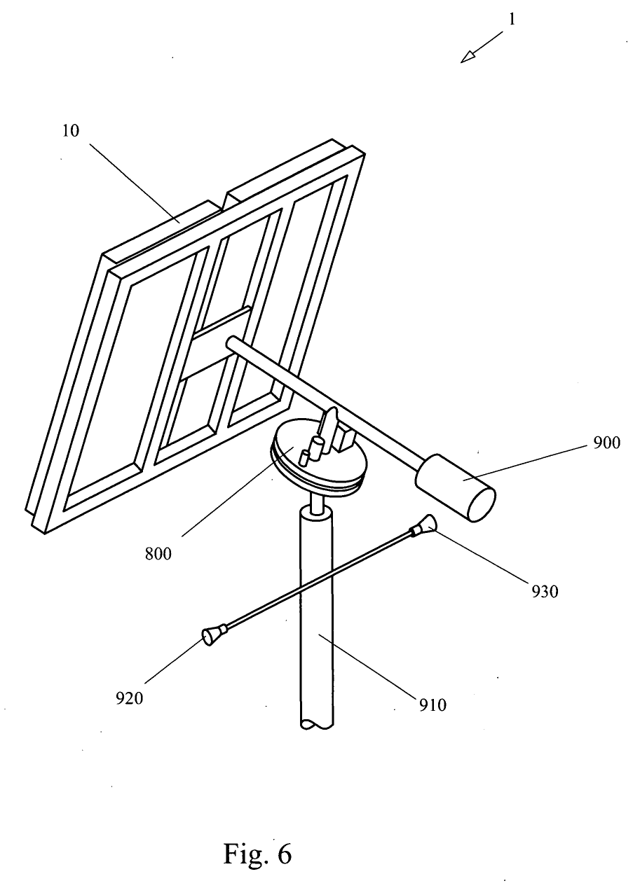

The method and apparatus of the present invention form a system for economically optimizing the amount of energy captured from the sun using a solar panel array. Each of the various components of the apparatus will be discussed in detail in following paragraphs, however, a review of FIG. 6 will provide the reader with an understanding of the basic architecture of the system.

Looking briefly at FIG. 6, the apparatus of the present invention is comprised of three major parts: an array of solar panels 10, a clutch assembly 800, and an array boom and counterweight assembly 900. Generally, the solar panel array 10 faces the sun and converts incoming light energy to direct current electrical energy. Clutch assembly 800 serves a number of purposes including acting as a mounting platform for the control electronics and battery as well as providing the wind stabilized pivot point needed for tracking the sun during a typical solar day. The array boom and counterweight assembly acts to center the weight of the apparatus at precisely the center point of the supporting post 910 thereby minimizing the load on the motor. Finally, AM sensor 920 and PM sensor 930 provide positional information for the control unit, becoming activated when the sun is detected in the morning and evening respectively.

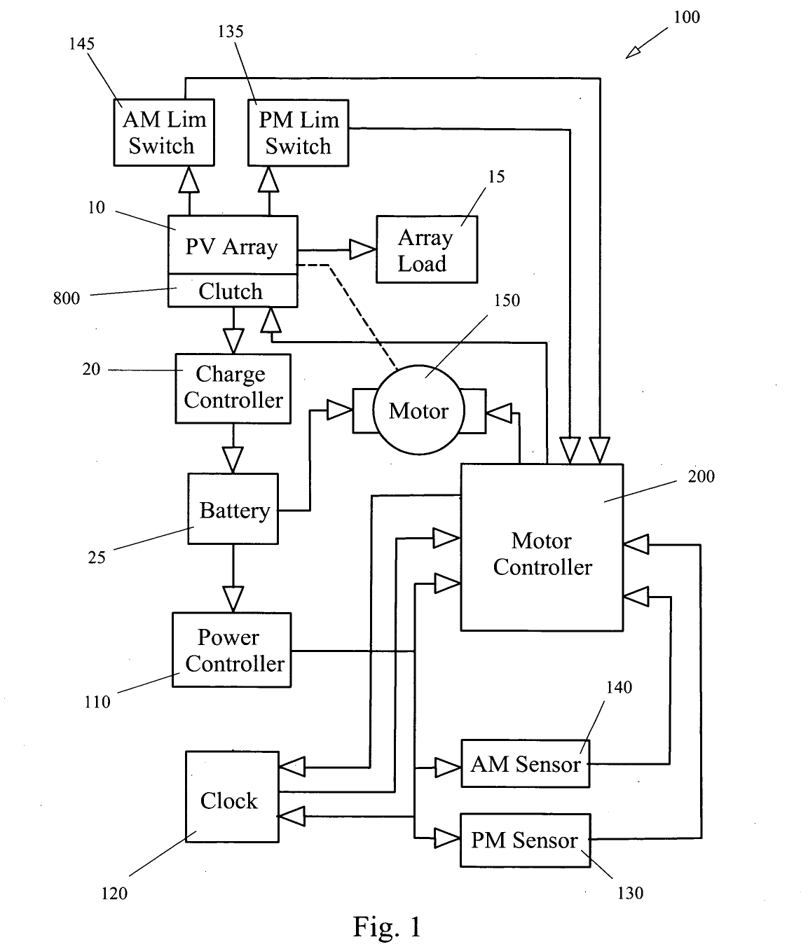

With the foregoing general description as a background, FIG. 1 presents a block diagram of the control electronics of the system of the present invention. Control system 100 is comprised of numerous elements, but only the main elements will be discussed in detail here to aid in clarity. Elements not discussed are well known in the art and do not pertain directly to the present invention, thus need not be presented for a complete understanding of the invention.

Solar panel array 10 is coupled to motor 150 via clutch 800. Motor controller 200 uses information from various sensors and switches to determine when and in what direction the motor 150 should run. Solar panel array 10 is also connected electrically to array load 15 and charge controller 20. Array load 15 can be any number of load devices including, but not limited to, batteries, pumps, inverters and DC driven generators. Charge controller 20 is used to manage the charge level of the battery 25.

Battery 25 is dedicated to providing power for the present invention and is not used for external load purposes. In a preferred embodiment, battery 25 is a 3 amp hour sealed lead acid type such as model PS1230 from Power-Sonic Corporation, San Diego, Calif. Power from battery 25 is delivered to motor 150 and to power controller 110. Power controller 110 then regulates the incoming raw battery voltage and delivers it to the electronic portions of the system including the motor controller 200, clock 120 and sensors 130 and 140.

Clock 120 is free running and outputs pulses at the rate of six KHz. These pulses are used by the logic contained within motor controller 200 to deliver the proper run time to motor 150. In a preferred embodiment clock 120 is a CDCE913 from Texas Instruments, Dallas, Tex. AM sensor 140 and PM sensor 130 are photo sensitive devices that react to the light of the sun. In a preferred embodiment AM sensor 140 and PM sensor 130 are both type QSE113 from Fairchild Semiconductor, San Jose, Calif. AM sensor 140 is positioned such that early morning light causes it to change state and PM sensor 130 is positioned to cause it to change state in the evening. As detailed below, the combination of these sensors is used to assist in the correct positioning of the solar panel array 10.

Also used to assist in the positioning of solar panel array 10 are limit switches 145 and 135. AM limit switch 145 is used to indicate to the logic of the motor controller 200 that the solar panel array 10 has reached its easterly most orientation. PM limit switch 135 is used to indicate to the logic of the motor controller 200 that the solar panel array 10 has reached its westerly most orientation. Both AM limit switch 145 and PM limit switch 135 are MS5-R from Velleman Inc., Fort Worth, Tex.

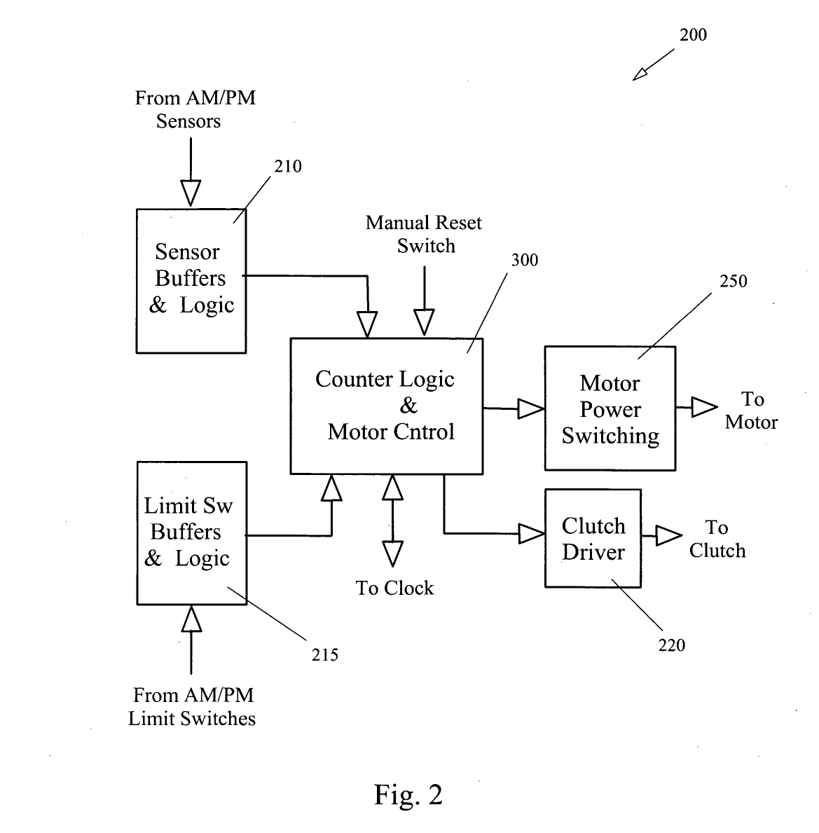

Referring now to FIG. 2, the motor controller 200 is shown in greater detail. Sensor buffers 210 and limit switch buffers 215 receive the raw signals form the AM/PM sensors and AM/PM limit switches respectively and de-bounce them. De-bouncing is a term of art that means simply that the raw incoming signal is conditioned to a shape and level suitable for use in the core logic of the motor controller 200. Counter logic and motor control block 300 contains the circuit level components that make the logical decisions needed to drive the motor and position the solar panel array. Motor power switching block 250 is comprised of the high power switching transistors required to activate the motor. Lastly, clutch driver 220 provides the control signals necessary to activate and deactivate the solenoid that mechanically stabilizes the solar panel array during times when the array is not being moved.

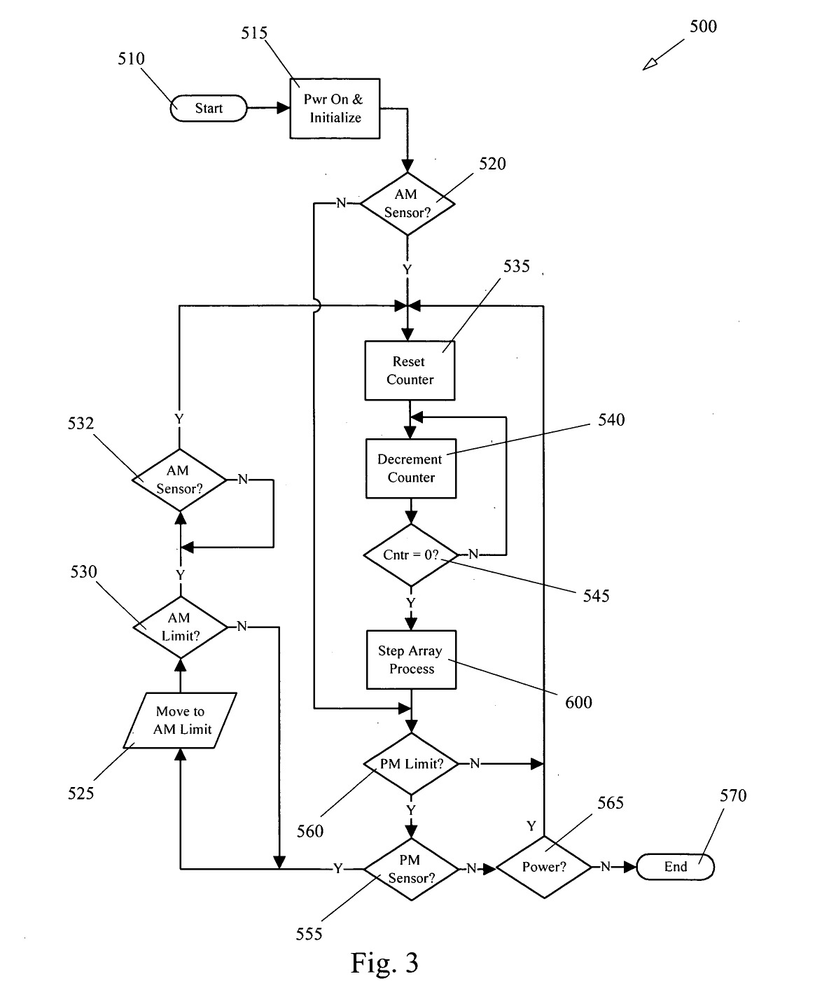

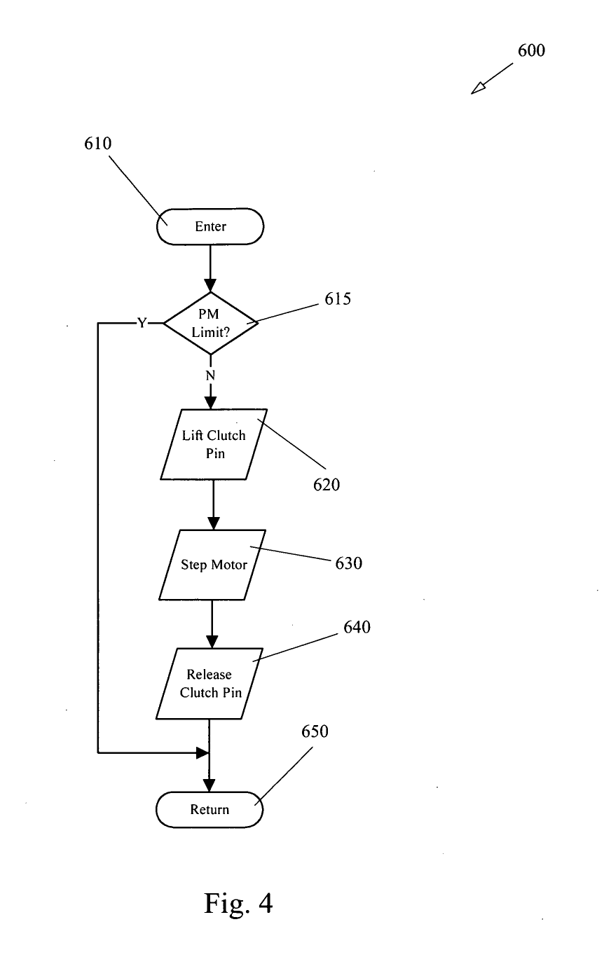

FIGS. 3 and 4 provide a discussion of the method of the present invention. Starting with FIG. 3, the process is entered at step 510. At step 515 a power on and initialization routine occurs. This routine is executed only once at the time that power is connected to the system. For example, after installation the solar panel array is approximately positioned and the battery terminals are connected. At this time all the logic is set to a known state and the clock starts delivering pulses to the motor control logic circuits.

Initial alignment of the solar panel array need only be approximate. In fact, it can be completely in error without damage to the system. This is so because once the clock starts delivering pulses to the motor control logic the system will step five degrees every 20 minutes. Supposing that the solar panel array was initially positioned toward the west, an evening setting, when it should have been positioned near the center, a noon time setting, the system will run until the PM limit switch 560 is activated. At this time the logic will check the PM sensor 555 to determine if the sun is indeed in the west. If not, the solar panel array will simply wait until the sun “catches up” to the array position. At that time the array will be driven to the morning position and wait until dawn when the system will now be in time sync with the sun. Thus one advantage of the present invention is that it will self correct for misalignment of the array.

Now suppose that the solar panel array was set to approximately the correct time of day with respect to the position of the sun. The motor control logic checks to see if the AM sensor 520 is active at step 520. If the answer is no, process flow passes to the PM sensor decision 555 to see if the PM sensor 555 is active. If the answer is no, the solar panel array must be somewhere between morning and evening, thus control passes to the reset counter process 535 and the process proceeds as described just above. However, if the AM sensor 520 is active, the yes path is followed to the reset counter process 535 since if the AM sensor 520 is active then the solar panel array must be pointed at the morning sun and the process should proceed normally.

At reset counter step 535 the step counter is set to 600. This number is determined by the run time necessary to move the solar panel array approximately six degrees, and represents 100 pulses per one degree step. The clock 120 contains an internal divider that reduces the internal six KHz rate to the 100 pulses per degree required by the motor. As explained in detail below, the six degree run time is necessary to ensure that the solenoid shaft 862 drops into the next successive five degree step hole. The process flow passes to decrement counter step 540 where the value of the counter is decremented by one. At counter=0 decision 545 the process checks to see if the counter has been decremented to zero. If not, it is not yet time to move the solar panel array, and the process loops back to the decrement counter step 540. If the counter has been decremented to zero it is time to move the solar panel array five degrees, so process flow passes to the step array process 600.

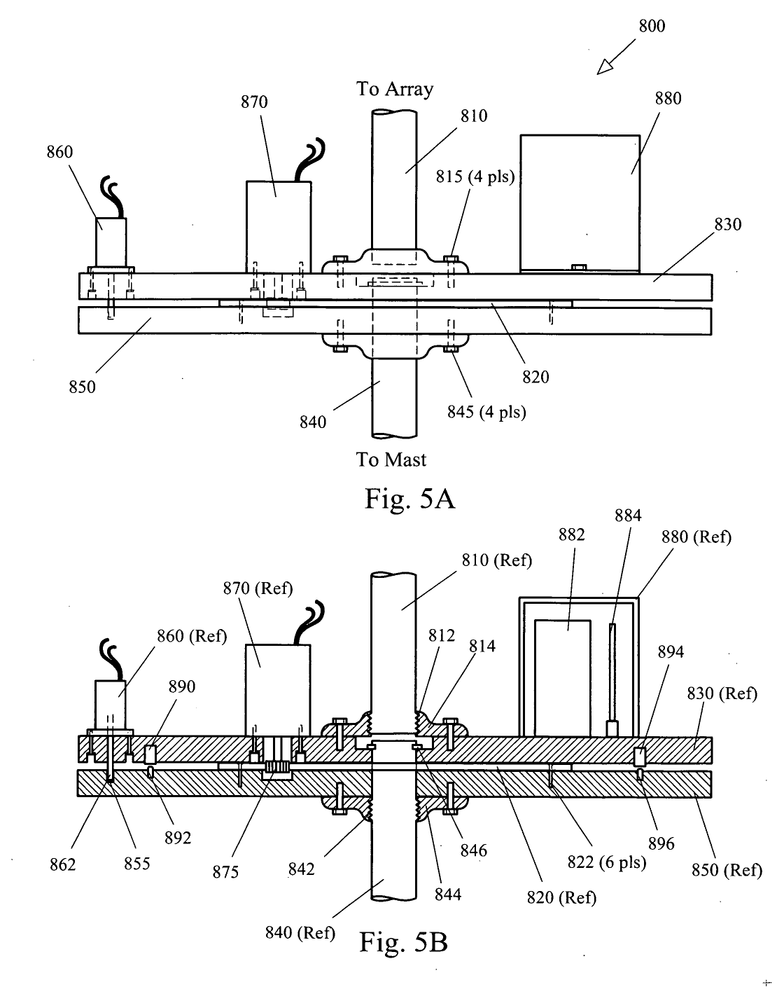

Looking now at FIG. 4, the step array process 600 is shown. The step array process is entered via enter step 610. The method of the present invention checks to see if the array has activated the PM limit switch (894 of FIG. 5B). This is required because, as discussed above, if the array was initially mis-positioned, or if cloudy conditions have caused the array to be out of sync with the sun, the array will be driven to the evening position and wait for the sun to activate the return to the morning position. If the evening position has been reached, the yes path is followed and the process flow returns since no further action is required until the sun catches up with the array.

If the evening position has not been reached, the No path is followed to the lift clutch pin step 620. At lift clutch pin step 620 the solenoid that controls the clutch pin is activated, lifting the pin and allowing the top half of the clutch to move. At step motor step 630 the motor is activated and the solar panel array begins to turn. Just after the motor is activated the process passes to release clutch pin step 640. Here the pin, which is spring loaded, tries to drop into the next five degree hole in the lower half of the clutch. Once the top half of the clutch has moved five degrees the pin drops, the motor is stopped and the process returns via return step 650. It must be noted, however, that the motor run time is set to six degrees in order to ensure that the array has moved the complete five degree step. Since the solenoid shaft 862 is spring loaded, it will seat in the five degree hole just prior to the cessation of the motor run time.

The process reenters the main flow at PM sensor decision 555. Here the process checks to see if the sun has reached the evening position in the sky. If the answer is no, the process loops back to the reset counter step 535 and the systems waits for the next five degree time to expire.

This loop will continue until the PM sensor decision 555 returns a yes answer. This means that the sun has reached the evening position in the sky. But in order to guarantee that the solar panel array has also reached its evening limit process flow passes to the PM limit decision 560. If the PM limit switch (135 of FIG. 1) has been activated, process flow transfers to the move to AM limit step 525 discussed below. If not, a no answer is followed out of PM limit decision 560 to the power decision 565. If power has been lost for some reason, the process ends at end step 570. If power is still on the system, and if the PM sensor is active but the PM limit switch is not, that must mean that the solar panel array has not yet reached its evening limit position. This can occur due to the sensitivity of the photo sensor or diffusion of the impinging light. In this case process flow passes back to reset counter step 535 in order to move the array another five degrees to the west. This loop will recur until the PM limit switch has been activated.

Returning to PM limit decision 560, and assuming that the PM limit switch has been activated, the system now moves the solar panel array to the morning position in anticipation of the next daily cycle. At move to AM limit step 525, the necessary actions are taken to move the solar panel array to the morning position. These include reversing the drive motor, lifting the clutch pin, and moving the array toward the morning position. At AM limit decision 530 the process checks to see if the solar panel array has arrived at the morning position. If not, control passes back to move to AM limit step 525. This loop will be prosecuted until the AM limit decision 530 returns a yes answer. This will occur as soon as the AM limit switch is activated.

Once the AM limit decision 530 returns a yes answer, process flow passes to the AM sensor decision 532. If the AM sensor decision 532 returns a no answer, a loop is set up that causes the system to enter a wait state. This occurs because once the solar panel array has reached the AM position, it is dark and no process activity is required until the sun rises to initiate the next daily cycle. As soon as the morning sun activates the AM sensor, a yes answer is returned from AM sensor decision 532 that passes process control to reset counter step 535 which begins the next daily cycle as just described.

One of the key features of the present invention is the clutch mechanism that both assures an accurate five degree step per twenty minute period and provides the necessary physical stability for the solar panel array during windy conditions. The former is needed to provide predictable array performance and the later is needed to compensate for the large sail area of the solar panels themselves. FIG. 5 provides the details of the clutch mechanism 800. Looking first at FIG. 5A, a side view of clutch 800 is shown. Clutch 800 is comprised of a lower plate 850, an upper plate 830 and a separator bushing 820. The upper plate 830 is moveable with respect to the lower plate 850. Array shaft stub 810 is fixably attached to upper plate 830 by bolts 815 in the customary manner. Likewise, mounting shaft 840 is fixably attached to the lower plate 850 by bolts 845 in the customary manner. Upper plate 830 and lower plate 850 are made from aluminum, but as will be understood, any suitable material could be sued without departing from the spirit of the invention. For example, plastic or PVC could be used for these plates. Separator busing 820 is made from Delrin® (from DuPont) in a preferred embodiment, however, as with the clutch plates, any suitable material could be used.

Mounted on the upper plate 830 are drive motor 870, solenoid 860, and electronics assembly 880. The purpose of the drive motor 870 is to move the upper plate 830 with respect to the lower plate 850. In a preferred embodiment the drive motor 870 is a Series 148 from Hansen Corporation, Princeton, Ind. The purpose of the solenoid 860 is to lift the stabilizing pin (discussed in detail below). In a preferred embodiment, the solenoid 860 is a model C-4 from Deltrol Controls, Milwaukee, Wis. The electronics assembly 880 is discussed below in connection with FIG. 5B, however, contained within this assembly are the battery and the logic board that implements the method of the present invention.

Turning now to FIG. 5B, a sectional view of clutch 800 is shown. Array shaft stub 810 attaches to upper plate 830 by means of a flange 814 that is threaded to accept the threads 812 on shaft stub 810. The drive shaft of drive motor 870 passes through upper plate 830. The terminal end of the drive shaft has a gear 875 that engages the inner circumference of separator bushing 820. The inner circumference of separator bushing 820 has mating teeth that accept the drive shaft gear such that upon application of power to the motor the upper plate 830 moves with respect to the lower plate 850. Since the lower plate 850 is mounted to a mast, and hence stationary, the solar panel array attached to the array shaft stub 810 will also move with respect to the lower plate 850. In this way the solar panel array is made to track the path of the sun over the period of a day.

Also mounted to upper plate 830 is solenoid 860. Solenoid 860 is of the type that, when power is applied, its shaft is retracted into the solenoid body. In the absence of power, the shaft 862 of the solenoid 860 drops into one of 35 receiving holes 855 disposed at five degree intervals near the outer circumference of the lower plate 850. Each time the solar panel array is stepped, the solenoid 860 is activated, the shaft 862 is retracted, and the array moved. Near the end of the movement time the solenoid 860 is deactivated and the shaft 862 drops into the next succeeding receiving hole. Once the shaft 862 has seated, the solar panel array is held in a stable physical configuration. In this way the apparatus of the present invention provides the solar panel array with the ability to withstand windy conditions.

Upper plate 830 has mounted to it electronics assembly 880. Within this assembly are battery 882 and logic board 884. The battery is used to provide enough storage to move the array from the evening position to the morning position and to maintain the process of the method of the present invention in an idle sate for a period of ten hours. This provides enough time to keep the process alive in the dark hours between sunset and sunrise. In a preferred embodiment, the battery is of the solid lead acid (SLA) type and is approximately 3 amp hours, for example, a PS1230 form Power-Sonic Corporation, San Diego, Calif.

Logic board 884 is comprised of the necessary logic circuits to implement the process presented in FIGS. 3 and 4 above. In a preferred embodiment the logic board 884 uses very low power integrated circuitry, for example, CMOS, such as that supplied by Motorola Inc. from Schaumburg, Ill., but it will be understood by those of skill in the art that any logic circuitry could be used. Moreover, while the apparatus of the present invention implements the logic in discreet integrated circuits, a field programmable logic array (FPLA) or other fully integrated solution could be used without departing form the spirit of the invention.

As mentioned briefly above, mounting shaft 840 attaches to lower plate 850. This is accomplished by means of flange 844 having internal threads that accept matching threads on shaft 840. Unlike the array shaft stub 810, however, the threads 842 of the mounting shaft 840 are located a distance inward from the terminal end of the shaft. This is done to allow mounting shaft 840 to protrude slightly into upper plate 830. A keeper ring 846 of the “c-clip” type then captures the mounting shaft 840. In this way a constant pressure is applied to separator bushing 820 which then maintains the contact between the gear 875 and the teeth on the inner circumference of the separator bushing 820. In turn, separator bushing 820 is attached to the lower plate 850 by means of screws 822.

The final main components of the clutch 800 are the limit switches. AM limit switch 890 and PM limit switch 894 are mounted in the upper plate 830. Thus when the upper plate moves with respect to the lower plate 850, the switches move also. Located at appropriate positions in the lower plate 850 are two pins 892 and 896. Pin 892 activates the AM limit switch 890 when the upper plate travels to the morning position. Pin 896 activates the PM limit switch 894 when the upper plate moves to the evening position. The purpose of these switches is to inform the process that the solar panel array has reached the end of its travel. As mentioned above, in a preferred embodiment AM limit switch 890 and PM limit switch 894 are both model MS5-R from Velleman Inc., Fort Worth, Tex., however, it will be recognized by those of skill in the art that other limit switches could be used without departing from the spirit of the invention.

While not shown, mounting shaft 840 attaches to a mast by means of an adjustable bracket. This bracket allows the apparatus of the present invention to be tilted to accommodate seasonal variations in the solar azimuth angle. Since this adjustable bracket is well understood in the art, and since it is not a critical part of the present invention, the details of the bracket are left out for clarity. However, the lack of a detailed discussion of the angle adjustment should not be read as a limitation on the scope of the invention. FIG. 6 provides an overview 1 of the major parts of the present invention as well as how they relate to a typical solar panel array system. The solar panel array 10 is comprised of one or more solar panels attached to a frame in the conventional manner. The solar panel array is then attached to the array shaft stub (810 of FIG. 5A). Because the array has significant mass, a counterweight 900 is used to balance that mass and thus place the load force from the apparatus directly over the mast 910. Mast 910 is of the conventional type and may be of any suitable material. Clutch 800 has the solar panel array 10 and counterweight assemblies mounted to it and thence mounted to the mast 910 via an adjustable bracket (not shown). Also mounted to the mast are AM sensor 920 and PM sensor 930. These sensors provide the signal to the logic board to inform the process that the sun is in either the morning or evening position. In a preferred embodiment the sensors are type QSE113 from Fairchild Semiconductor, San Jose, Calif., however, it will be understood by those of skill in the art that other sensors could be used without departing from the spirit of the invention. Each of these sensors is mounted in a conical housing in order to disallow ambient daytime light form triggering the sensor. The angle of the cone is set, in a preferred embodiment, at 10 degrees from the centerline of the cone. Thus if the sun has traversed past the first five degree step, the sensor will not be triggered.

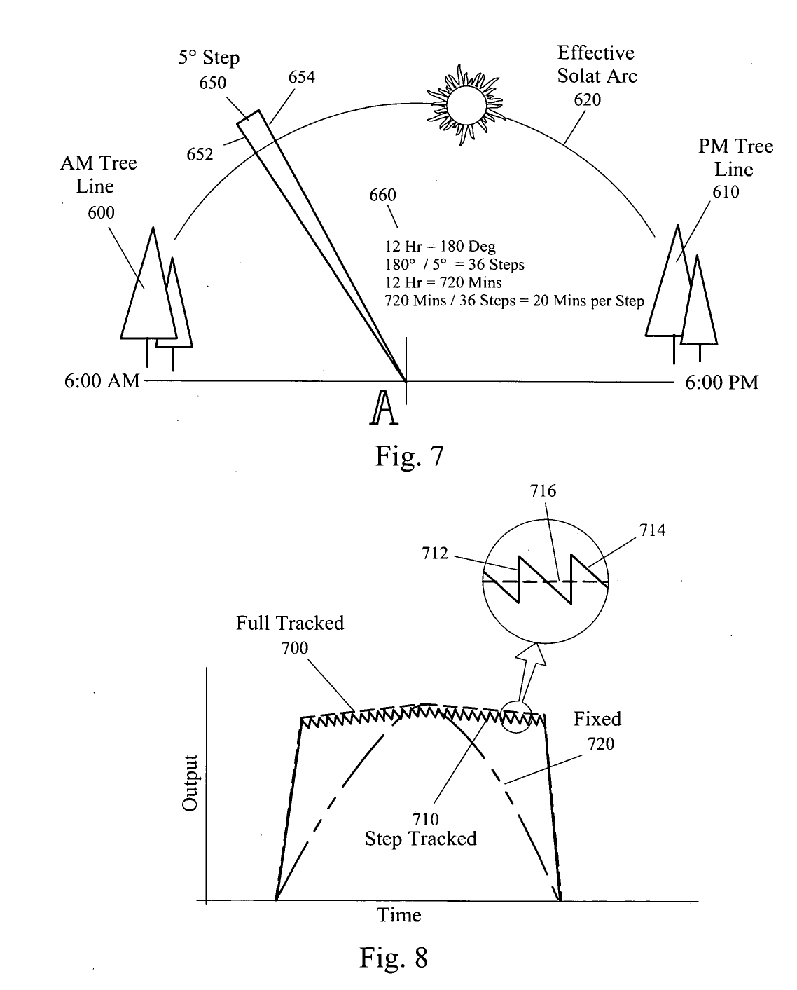

FIGS. 7, 8 and 9 provide the technical/theoretical basis for the operation of the present invention. Starting with FIG. 7, the parameters of a typical operational situation are shown. The apparatus of the present invention is located at point A. Both AM tree-line 600 and PM tree-line 610 represent the obstacles to impinging sunlight typical of most installations. Usable impinging light from the sun along solar arc 620 is thus limited to that clear exposure between the two tree-lines. A typical five degree step 650 is shown at some point mid-morning. Leading edge 652 is the point at which the apparatus of the present invention has just completed a step function. Approximately twenty minutes will pass at which time the sun will be at the trailing edge 654 of the five degree step. At this time the method of the present invention, under control of the clock, will again cause the solar panel array to step to the next position.

The calculation 660 in the inset provides the derivation of the five degree step size and timing. Assuming a generally horizontal horizon and generally twelve hours of daylight in any given day, the solar arc will cover 180 degrees in twelve hours. It is recognized that a set of variables particular to each installation, for example tree lines 600 and 610, will reduce the horizon and time, however, for purposes of discussion, the above assumptions can be applied. Since there are 36 five degree steps in 180 degrees, and since there are 720 minutes in twelve hours, then each five degree step represents 20 minutes. This 20 minute period is the amount of time the solar array spends at each five degree step.

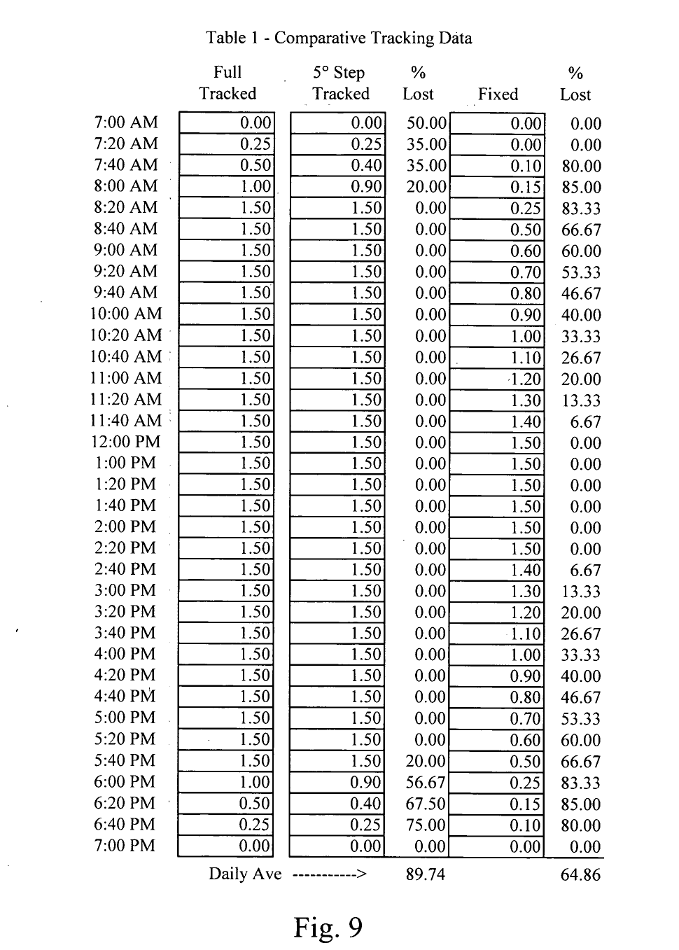

Referring now to FIG. 8, a graphical comparison of three methods discussed above is presented. The methods include a fixed array, a fully tracked array and the step function tracked array of the present invention. Line 720 describes the light energy captured during a solar day by the fixed array method. As can be seen, as the sun's angle becomes more and more perpendicular to the array, the amount of energy captured increases. However, both before and after perpendicularity is achieved the energy captured drops off significantly. As detailed in the table of FIG. 9, a fixed array can be expected to capture only about 65% of the energy of a fully tracked array.

Line 700 in FIG. 8 presents the light energy captured by a fully tracked array. As can be seen, once the sun has cleared the tree-line the captured energy rises quickly to near its peak value. This is because the impinging sunlight is striking the solar array at approximately 90 degrees. This peak value will be maintained for the balance of the solar day until the sun passes below the PM tree-line. The table of FIG. 9 presents the data for this type of system and is the 100 percent reference for the other array data.

Line 710 of FIG. 8 presents the light energy captured by the method and apparatus of the present invention. The primary difference between the fully tacked array method and the method of the present invention is the appearance of a saw-tooth energy capture function along the top portion of the curve. Like the fully tracked method, the method of the present invention reaches its near maximum energy capture as soon as the sun has cleared the AM tree-line. This is because, as a result of the clock control, the impinging sunlight is striking the solar array at approximately 90 degrees. Also like the fully tracked method, the method of the present invention stops producing energy at the time the sun passes below the PM tree-line.

The primary difference is detailed in the inset of FIG. 8. Once the step function has been completed under control of the method of the present invention, the energy captured peaks, such as at 712. This relates directly to the leading edge of the five degree step (652 of FIG. 7). As the sun continues its path along the solar arc, the energy captured will decrease as shown by line 714. The decrease will continue until the next step function is completed. The average of the peaks and valleys of the saw-tooth is shown by line 716. It is the average of the saw-tooth that represents the total energy captured by the step function tracked method. As shown in the data in the table of FIG. 9, the step tracked method will produce nearly 90 percent of the energy captured by a fully tracked method. Of course a step size of other than five degrees could be used without departing from the spirit of the invention. If a larger step size is used, a lower average power output will occur. Conversely, if a smaller step size is used the output will mote closely approximate that of the fully tracked array.

The primary advantages of cost and simplicity make the sacrifice of 10 percent attractive for many, if not most applications. For example, remote pumping applications that traditionally use a fixed array can make use of the present invention to increase the output flow. Other applications such as portable lighting, remote communications and landscape lighting may also benefit.

A first advantage of the present invention is that the apparatus is relatively inexpensive when compared to a fully tracked method. Depending on the exact technology involved, contemporary full tracked systems range in cost from the low thousands of dollars to upwards of ten thousand dollars. Given the simple, yet stable mechanical design, coupled to the inexpensive control method, the step tracker of the present invention could be manufactured at a cost of less than half of the least expensive fully tracked method.

A second advantage of the present invention is that it is simpler than fully tracked methods. Contemporary fully tracked systems operate on one of several different principles. Some use inert gas, some use fluid pressure and still others use thermally sensitive metals to detect the need to move the array in response to a temperature change brought about by the sun's rays striking some part of the mechanism. Each of these is complex and requires special skill to install and maintain. The apparatus of the present invention, in contrast, requires only simple installation process.

A third advantage of the present invention is that it is self correcting when a positional error occurs. If for some reason, power to the system is lost, or more likely, the mechanism became improperly oriented, a single day/night cycle will allow the method of the present invention to realign the array and carry forward normally.

I claim:

1. An apparatus for moving a solar panel array to approximately face the sun as it moves across the daytime sky, comprising:
a clutch mechanism capable of supporting a solar panel array having contained within said clutch mechanism a motor capable of driving said solar panel array;
an AM sensor to indicate the presence of the morning sun;
a PM sensor for determining the presence of the evening sun, and;
a control mechanism for determining when to move said solar panel array such that said solar panel array approximately faces the sun during daytime hours.

2. The control mechanism of claim 1 further comprised of:
a motor controller;
a clock;
an AM limit switch;
a PM limit switch;
a battery;
a battery charge controller;
a battery power controller, and;
a clutch pin solenoid.

3. The clutch mechanism of claim 1 further comprising;
a lower clutch plate fixably attached to a mast;
an upper clutch plate fixably attached to a solar panel array and separated from said lower clutch plate by a bushing such that said upper clutch plate is free to move rotationally with respect to said lower clutch plate, said upper clutch plate further comprised of,
a motor;
a battery;
an AM limit switch;
a PM limit switch;
a solenoid, and;
a control mechanism for controlling said motor and said solenoid such that in response to signals supplied by said AM limit switch and said PM limit switch in combination with an AM sensor and a PM sensor said solar panel array approximately faces the sun during daytime hours.

4. The clutch mechanism of claim 3 where the lower clutch plate has an array of holes spaced about a semicircle at five degree increments, said array of holes positioned such that the most counterclockwise hole of said array of holes is oriented towards the morning horizon and the most clockwise hole of said array of holes is oriented toward the evening horizon, each of said holes of said array of holes capable of receiving a pin operated by a solenoid on the upper clutch plate, said pin providing positive stabilizing force at each of said holes.

5. A method to control an apparatus for moving a solar panel array to approximately face the sun as it moves across the daytime sky, comprising:
determining, in response to an AM sensor signal, the presence of the sun near the morning horizon;
detecting the current position of a solar panel array to verify that said solar panel array is approximately facing said sun;
resetting a decrementable counter;
decrementing said decrementable counter by one;
checking said decrementable counter continuously until said decrementable counter equals zero;
moving said solar panel array clockwise five degrees;
repeating said detecting step, said resetting step, said decrementing step, and said moving step until said solar panel array activates a PM limit switch, and;
driving said solar panel array in a counterclockwise direction until an AM limit switch is activated.

6. The detecting step of claim 5 further comprised of:
determining, in response to an AM sensor signal, the presence of the sun near the morning horizon;
checking the PM limit signal, in the absence of a positive signal from said AM sensor, to determine whether the solar panel array is in the evening position;
resetting a decrementable counter;
decrementing said decrementable counter by one;
checking said decrementable counter continuously until said decrementable counter equals zero;
moving said solar panel array five degrees;
repeating said detecting step, said resetting step, said decrementing step, and said moving step until said solar panel array activates a PM limit switch;
continuing to repeat said resetting step, said decrementing step, and said moving step until both said PM limit signal and the PM sensor signal are positive;
moving said solar array counterclockwise until the AM limit signal is positive, and;
monitoring the said AM sensor signal to identify the beginning of a new daily cycle.

7. The moving step of claim 5 further comprised of:
entering the moving step from normal process operation in response to a decrementable counter reaching a zero state;
determining, in response to a PM limit signal, the position of a solar panel array at its most clockwise travel;
lifting a clutch pin in response to the absence of said PM limit signal;
applying power to a motor to rotate said solar panel array five degrees in a clockwise direction;
releasing said clutch pin, or;
bypassing said lifting step, said applying power step and said releasing step in the presence of said PM limit signal, and;
returning to said normal process operation.
